(19) United States
(12) Patent Application Publication
(10) Pub. No.: US 2024/0313168 A1
(43) Pub. Date: Sep. 19, 2024

(54) OPTOELECTRONIC LIGHT EMITTING DEVICE

(71) Applicant: ams-OSRAM International GmbH, Regensburg (DE)

(72) Inventors: Roland Schulz, Regensburg (DE); Markus Burger, Laaber (DE); Moritz Laubscher, Göllheim (DE)

(21) Appl. No.: 18/576,349

(22) PCT Filed: Jul. 8, 2022
(86) PCT No.: PCT/EP2022/069183

§ 371 Date: Jan. 3, 2024

(30) Foreign Application Priority Data
Jul. 9, 2021 (DE) 10 2021 117 858.4

(51) Int. Cl. H01L 33/50

(52) U.S. Cl. CPC H01L 33/502; H01L 2933/0041; H01L 2933/0091

(57) ABSTRACT

In an embodiment an optoelectronic light emitting device includes at least one light emitting surface configured to emit light of a first wavelength and a conversion layer arranged on the at least one light emitting surface, wherein the conversion layer has a substantially transparent matrix material having a first refractive index in which it is embedded: a plurality of light conversion particles configured to convert the light of the first wavelength into light of a second wavelength and a plurality of homogenization particles consisting essentially of a material having a second refractive index, wherein the first and second refractive indices differ by a value of at most 0.1. The conversion layer of the device has a thickness of less than or equal to 30 μm and a particle size distribution of the light conversion particles substantially corresponds to a particle size distribution of the homogenization particles.

### CROSS-REFERENCE TO RELATED APPLICATIONS

This patent application is a national phase filing under section 371 of PCT/EP2022/069183, filed Jul. 8, 2022, which claims the priority of German patent application 10 2021 117 858.4, filed Jul. 9, 2021, each of which is incorporated herein by reference in its entirety.

### TECHNICAL FIELD

The present invention deals with methods and technologies for manufacturing a conversion layer, in particular a very thin conversion layer, on optoelectronic components such as LEDs, in particular LEDs with very small dimensions, also known as μLEDs.

### BACKGROUND

At present, conversion layers on optoelectronic components, such as LEDs, are usually applied to the light emitting surface of the optoelectronic components by means of a spraying process. For this purpose, a suspension (slurry) consisting of light conversion particles in a silicone matrix, for example, is sprayed onto the light emitting surface as homogeneously as possible.

However, effects such as surface tensions cause the light conversion particles to agglomerate on the light emitting surface, i.e. to accumulate in partial areas of the component surface. The agglomerates/accumulations lead to spatial fluctuations in the color location across the light emitting surface. This in turn leads to an inhomogeneity of the luminance of the light converted by the conversion layer.

With a given concentration of light conversion particles in the conversion layer in order to obtain a desired integral chromaticity coordinate (integrating sphere measurement) of the light converted by the conversion layer, it is possible to obtain the desired chromaticity coordinate, but the agglomerates/accumulations lead to a selectively different chromaticity coordinate or a higher or lower chromaticity coordinate. This means that the light emitted by the light emitting surface is converted more strongly in the areas of the agglomerates/accumulations and is not, or only barely, converted in areas between the accumulations. This undesirable spatial difference in color location is also called Color over Space behavior (CoS).

Other possibilities for applying conversion layers to optoelectronic components are foil printing, dispensing, or electrophoretic deposition of particles, but the above-mentioned effects also occur, which leads to an undesirable spatial color location difference.

### SUMMARY

Embodiments provide an optoelectronic light emitting device with a conversion layer and a method for manufacturing an optoelectronic light emitting device with a conversion layer which has improved color and luminance homogeneity.

An optoelectronic light emitting device according to the invention comprises at least one light emitting surface which emits light during operation of the optoelectronic light emitting device and a conversion layer arranged on the at least one light emitting surface. The conversion layer comprises a substantially transparent matrix material with a first refractive index. A plurality of light conversion particles, for converting a light of a first wavelength emitted from the light emitting surface into light of a second wavelength, and a plurality of homogenization particles, consisting of a material having a second refractive index, are embedded in the conversion layer or the matrix material. The first and second refractive indices essentially do not differ or differ by a value of 0.1 at most.

The core of the invention is to add homogenization particles, or foreign particles that do not comprise light-converting material, to the conversion layer in addition to the light conversion particles. The admixed homogenization particles ensure that agglomerates or accumulations of particles in the conversion layer are formed not only by light conversion particles but also by homogenization particles. Due to the larger total number, a higher spatial homogeneity of the light conversion particles in the conversion layer is achieved with a predetermined concentration of light conversion particles in the conversion layer in order to obtain a desired integral color location of the light converted by the conversion layer. The light conversion particles present are accordingly distributed more homogeneously on the light emitting surface, resulting in improved color and luminance homogeneity of the light emitted by the optoelectronic light emitting device.

This can be particularly advantageous in applications of the optoelectronic light emitting device in which the optoelectronic light emitting device is used close to its imaging limit, for example when images or logos are projected onto a distant surface by means of the optoelectronic light emitting device. With an increased chromaticity coordinate difference (CoS) over emission surfaces of the optoelectronic light emitting device, for example in a case without the addition of homogenization particles, colour fringing and a lower contrast of the projection on the distant surface would be more noticeable. By adding the homogenization particles, on the other hand, an improved colour and luminance homogeneity of the light emitted by the optoelectronic light emitting device and thus high contrasts and sharp edges of a projection on a distant surface can be achieved.

In addition, the homogenization particles have no or only a very low light-scattering effect within the conversion layer, since their material has an essentially identical refractive index to the matrix material surrounding the particles. Accordingly, there is no or only a very small refractive index jump between the homogenization particles and the matrix material surrounding the particles, so that light passing through the conversion layer is not scattered or only barely scattered by the homogenization particles.

In some embodiments, the particle size distribution or grain size distribution of the light conversion particles or phosphor particles essentially corresponds to the particle size distribution or grain size distribution of the homogenization particles. In particular, the mean value of the particle sizes or grain sizes of the phosphor particles essentially corresponds to the mean value of the particle sizes or grain sizes of the homogenization particles. Ideally, the light conversion particles have the same size distribution as the homogenization particles.

In some embodiments, the conversion layer has a thickness of less than or equal to 30 μm and in particular a thickness of less than or equal to 15 μm. The conversion layer is correspondingly particularly thin. This can be particularly necessary or advantageous if the conversion layer is applied to particularly small optoelectronic components, i.e. optoelectronic components with particularly small dimensions. In particular, the thickness of the conversion layer should not exceed the dimensions of the optoelectronic component to which the conversion layer is applied.

It can also be advantageous for both the light conversion particles and the homogenization particles to be very small. In particular, the light conversion particles as well as the homogenization particles can have a size of a few micrometers and in particular a few sub-micrometers. For example, the light conversion particles and the homogenization particles can be in the form of nanospheres or nanoparticles. This can be particularly advantageous in the case of a very thin conversion layer, as a larger number of particles can be distributed more homogeneously and in several layers in the conversion layer. In the case of a larger particle size, on the other hand, just a few particles would cover the entire light emitting surface and a homogeneous distribution of the particles would be difficult to achieve.

In some embodiments, the at least one light emitting surface has an edge length of less than or equal to 40 μm, or an area of less than or equal to 100 μm². This may be due in particular to the fact that the light emitting surface is part of particularly small optoelectronic components, i.e. optoelectronic components with particularly small dimensions.

In some embodiments, light-scattering particles made of a material with a third refractive index are additionally embedded in the conversion layer. The third refractive index differs from the first and second refractive indices. Between the light-scattering particles and the matrix material surrounding the particles or the homogenization particles, there is in particular a sufficiently large refractive index jump so that light passing through the conversion layer is scattered by the light-scattering particles.

In some embodiments, the particle size distribution or grain size distribution of the light-scattering particles substantially corresponds to the particle size distribution or grain size distribution of the homogenization particles and/or the light conversion particles. In particular, the mean value of the particle sizes or grain sizes of the light-scattering particles essentially corresponds to the mean value of the particle sizes or grain sizes of the homogenization particles and/or the light conversion particles. Ideally, the light-scattering particles have the same size distribution as the homogenization particles and/or as the light conversion particles.

In some embodiments, the optoelectronic light emitting device comprises at least one LED or at least one pixelated LED chip. The at least one light emitting surface is formed by a light emitting surface of the LED or the pixelated LED chip. In particular, the LED or the pixelated LED chip can also be referred to as a micro-LED, also known as a μLED, or as a μLED chip, especially if its light emitting surface has edge lengths in the range from 100 μm to 10 μm or even significantly smaller edge lengths.

In some embodiments, the LED or pixelated LED chip may be an unhoused semiconductor chip. Unhoused means that the chip does not have a package around its semiconductor layers, such as a “chip die”. In some embodiments, unhoused may mean that the chip is free of any organic material. Thus, the unhoused device does not contain any organic compounds that contain carbon in covalent bonding.

In some embodiments, the optoelectronic light emitting device comprises a wafer structure with a plurality of light emitting components grown on the wafer. The at least one light emitting surface is formed by a light emitting surface of the light emitting components grown on the wafer. The light emitting components can be present on the wafer in the form of unhoused semiconductor chips. Unhoused means that the chip has no housing around its semiconductor layers, such as a “chip die”. In some embodiments, unhoused may mean that the chip is free of any organic material. Thus, the unhoused device does not contain any organic compounds that contain carbon in covalent bonding.

In some embodiments, the matrix material comprises at least one of the following materials:
a silicone;
an epoxy;
a polysiloxane;
a polysilicon;
a glassy material; and
a material based on glass.

In some embodiments, the matrix material comprises a substantially transparent material. In this context, substantially transparent means that the material is at least transparent to the light emitted from the light emitting surface and the light converted by the light conversion particles. In other words, the matrix material absorbs little or no light emitted by the light emitting surface and the light converted by the light conversion particles.

In some embodiments, the light conversion particles comprise, for example, phosphors for converting the light of a first wavelength emitted by the light emitting surface into light of a second wavelength different from the first wavelength.

In particular, the light conversion particles are designed to convert light of a first wavelength into light of a second wavelength that is different from the first wavelength. For example, the light conversion particles can be designed to convert blue light into yellow light in order to obtain white light by mixing the blue and yellow light.

In some embodiments, the homogenization particles comprise at least one of the following materials:
Glass/SiO₂;
highly refractive polymers;
PP;
PE; and
Sapphire crystal/Al₂O₂.

In some embodiments, the mechanical properties of the conversion layer can be specifically influenced by the addition of the homogenization particles. On the one hand, this can be influenced by the concentration of the homogenization particles added to the conversion layer and/or by the choice of material and shape of the homogenization particles.

In some embodiments, the number of homogenization particles of all particles present in the conversion layer is at most 50%. In particular, the number of all homogenization particles and optional light-scattering particles of all particles present in the conversion layer is at most 50%. In other words, the number of light conversion particles of all particles in the conversion layer is greater than or equal to 50%. This ensures sufficient light conversion.

In some embodiments, the particles embedded in the conversion layer have a distribution that is as homogeneous as possible. In particular, the light conversion particles have a distribution in the conversion layer that is as homogeneous as possible.

In some embodiments, agglomerates/accumulations of particles embedded in the conversion layer are formed in the conversion layer. The agglomerates each comprise a subset of the light conversion particles and a subset of the homogenization particles. Contrary to the above embodiment, the particles may accordingly have an “inhomogeneous” distribution, since the particles may be arranged in the form of clusters and not completely uniformly on the light emitting surface. However, it should be noted that the addition of the homogenization particles results in a more homogeneous distribution, in particular of the light conversion particles, than in the case where no homogenization particles are added to the conversion layer, since the light conversion particles are distributed over several agglomerates. Accordingly, on this side one can speak of a homogeneous distribution of the particles, in particular a homogeneous distribution of the light conversion particles.

A method for manufacturing an optoelectronic light emitting device according to the invention comprises the steps of:
Providing at least one light emitting surface during operation of the optoelectronic light emitting device; and
Application of a conversion layer to the at least one light emitting surface.

The conversion layer comprises a substantially transparent matrix material having a first refractive index, and a plurality of light conversion particles, for converting a light of a first wavelength emitted from the light emitting surface into light of a second wavelength, and a plurality of homogenization particles, consisting of a material having a second refractive index, are embedded in the conversion layer or the matrix material. The first and second refractive indices essentially do not differ or differ at most by a value of 0.1 or at most by 0.05.

In some embodiments, the step of applying the conversion layer comprises a spraying process. For this purpose, it can be particularly advantageous that the particle size distribution or particle size distribution of the light conversion particles essentially corresponds to the particle size distribution or particle size distribution of the homogenization particles and the particle size distribution or particle size distribution of light-scattering particles optionally embedded in the conversion layer. Accordingly, it may be possible, for example, to continue using an existing spraying process for applying a conversion layer without homogenization particles without changing the process.

In some embodiments, the step of applying the conversion layer to the light emitting surface comprises electrophoretic deposition (EPD) of the light conversion particles and/or the homogenization particles and/or optionally light-scattering particles embedded in the conversion layer. The matrix material can then be applied to the particles by means of a spraying process, dispensing or lamination.

In some embodiments, the conversion layer is in the form of a suspension (slurry) at the time of application, which comprises the matrix material, light conversion particles, homogenization particles and optionally light-scattering particles. After the suspension has been applied to the light emitting surface, in particular by means of a spraying process, it hardens and forms the conversion layer.

In some embodiments, the step of applying the conversion layer comprises a lamination or bonding step. In particular, this may be the case if the conversion layer is already present as a film comprising the matrix material, light conversion particles, homogenization particles and optionally light scattering particles, and is laminated or adhered to the light emitting surface.

### BRIEF DESCRIPTION OF THE DRAWINGS

In the following, embodiments of the invention are explained in more detail with reference to the accompanying drawings.

FIGS. 1A to 1C show steps for manufacturing an optoelectronic light emitting device, and a microscopic image of a top view of a conversion layer of an optoelectronic light emitting device;

FIGS. 2A and 2B show steps for manufacturing an optoelectronic light emitting device and the optoelectronic light emitting device according to some aspects of the proposed principle; and

FIGS. 3A and 3B show respectively, a sectional view of two embodiments of an optoelectronic light emitting device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

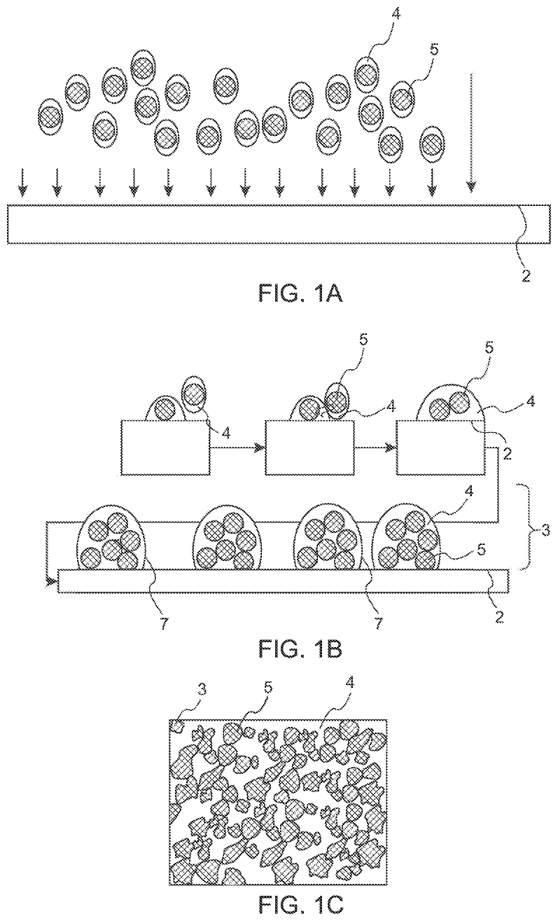

FIGS. 1A and 1B each show a highly simplified diagram of steps in the manufacture of an optoelectronic light emitting device and of effects occurring during the manufacture of an optoelectronic light emitting device. In particular, the figures show a step of applying a conversion layer 3 to a light emitting surface 2 of an optoelectronic light emitting device and effects occurring during this step.

By means of a spraying process, a suspension (slurry) comprising a matrix material 4 and a plurality of light conversion particles 5 is applied to the light emitting surface 2, as shown in FIG. 1A. This is shown schematically by the vertical arrows in FIG. 1A. As a result of the spraying process, the light conversion particles 5 are coated by the matrix material 4 and in this form are applied to the light emitting surface 2 or to light conversion particles 5 already present on the light emitting surface 2.

Light conversion particles 5 arranged next to and/or on top of each other form agglomerates 7 or accumulations on the light emitting surface 2 as long as the matrix material 4 has not yet hardened, for example due to surface tensions. Accordingly, the light conversion particles 5 are not distributed homogeneously on the light emitting surface 2, but “grow together” in partial areas of the light emitting surface 2 to form agglomerates 7. This effect is illustrated step by step for two light conversion particles 5 in the upper half of FIG. 1B, so that the agglomerates 7 shown in the lower half of FIG. 1B each form with a subset of the plurality of light conversion particles 5 on the light emitting surface 2.

The agglomerates 7, each with a subset of the multitude of light conversion particles 5, lead to a selectively higher or color location in the corresponding area of the conversion layer 3. This means that the light emitted by the light emitting surface 2 is converted more strongly in the areas of the agglomerates 7 and is not, or only barely, converted in areas between the agglomerations. This leads to an undesirable spatial chromaticity aberration (CoS).

FIG. 1C shows a microscopic image of a top view of a conversion layer 3 of an optoelectronic light emitting device produced in this way. The spatial inhomogeneity within the conversion layer 3 can be clearly seen, as the light conversion particles 5 are obviously not evenly distributed within the matrix material, but form agglomerates 7.

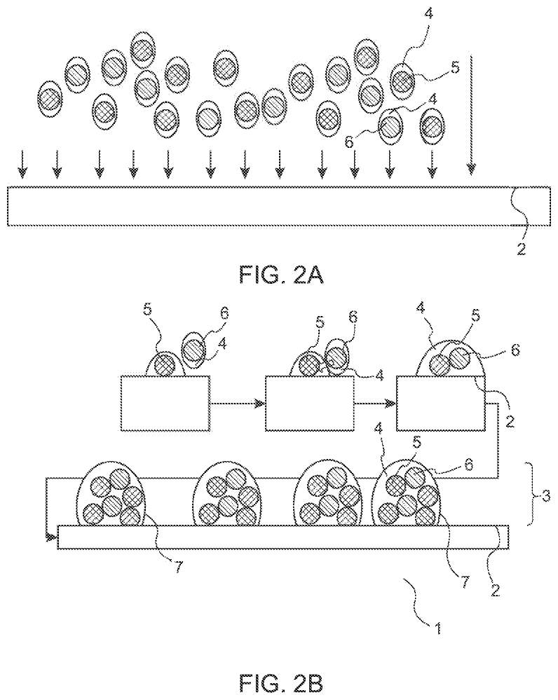

FIGS. 2A and 2B each show a highly simplified schematic of steps of an improved manufacturing process of an optoelectronic light emitting device 1 according to some aspects of the proposed principle, or the effects occurring therein. In particular, the figures show an improved step of applying a conversion layer 3 to a light emitting surface 2 of an optoelectronic light emitting device 1 according to some aspects of the proposed principle.

In contrast to the spraying process shown in FIG. 1A, the suspension (slurry) applied to the light emitting surface 2, as shown in FIG. 2A, comprises a matrix material 4, a plurality of light conversion particles 5 and a plurality of homogenization particles 6. This suspension is applied to the light emitting surface 2 as described above, which is shown schematically by the vertical arrows in FIG. 2A. As a result of the spraying process, the light conversion particles 5 and the homogenization particles 6 are each coated by the matrix material 4 and in this form impinge on the light emitting surface 2 or on light conversion particles 5 and/or homogenization particles 6 already present on the light emitting surface 2.

As long as the matrix material 4 has not yet hardened, light conversion particles 5 and/or homogenization particles 6 arranged next to and/or on top of each other form agglomerates 7 or accumulations on the light emitting surface 2 due to surface tensions, for example. Due to the added homogenization particles 6, however, the agglomerates 7 do not exclusively comprise light conversion particles 5 but also homogenization particles 6. An equal number of light conversion particles 5—compared to the case where no homogenization particles 6 are added—is thus distributed over a larger area and more homogeneously over the light emitting surface 2, since homogenization particles 6 are located within the agglomerates between light conversion particles 5. This effect is exemplified for a light conversion particle 5 and a homogenizing particle 6 step by step in the upper half of FIG. 2B, so that the agglomerates 7 shown in the lower half of FIG. 2B are formed on the light emitting surface 2, each with a subset of the plurality of light conversion particles 5 and a subset of the plurality of homogenization particles 6.

Since the agglomerates 7 each comprise a subset of the plurality of light conversion particles 5 and a subset of the plurality of homogenization particles 6 compared to the conversion layer shown in FIG. 1B, the light conversion particles 5 are spaced further apart than in the case where the agglomerates comprise only light conversion particles 5. As a result, the light conversion particles 5 present are distributed correspondingly more homogeneously on the light emitting surface 2, resulting in improved color and luminance homogeneity of the light emitted by the optoelectronic light emitting device 1.

In addition, the homogenization particles 6 have no or only a very low light-scattering effect within the conversion layer 3, since their material has an essentially identical refractive index as the matrix material 4 surrounding the particles 5,6. Between the homogenization particles 6 and the matrix material 4 surrounding the particles 5,6 there is correspondingly no or only a very small refractive index jump, so that light passing through the conversion layer 3 is not scattered or only barely scattered by the homogenization particles 6.

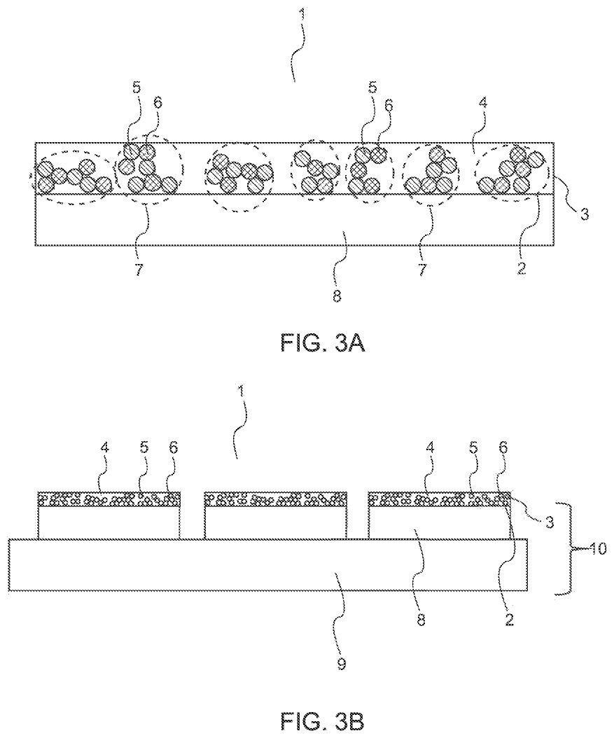

FIG. 3A shows a sectional view of an optoelectronic light emitting device 1 produced by the method step described above. The light emitting device comprises a semiconductor body 8 having a light emitting surface 2 on which a conversion layer 3 is disposed. The conversion layer 3 comprises a matrix material 4 having a first refractive index, in which a plurality of light conversion particles 5 and a plurality of homogenization particles 6 are embedded. The particles 5, 6 form agglomerates 7 or accumulations within the conversion layer 3, which are formed during the manufacturing step of the conversion layer 3. The light conversion particles 5 are designed to convert light of a first wavelength emitted by the light emitting surface 2 into light of a second wavelength. The homogenization particles 6 consist of a material with a second refractive index, wherein the first and the second refractive index differ at most by a value of 0.1.

FIG. 3B shows a sectional view of a further optoelectronic light emitting device 1 according to some aspects of the proposed principle. The light emitting device 1 comprises a wafer structure 10 having a plurality of light emitting devices 8 grown on a carrier substrate 9. The light emitting devices 8 each have a light emitting surface which forms the light emitting surfaces 2. A conversion layer 3 is arranged on each of the light emitting surfaces 2. The conversion layer 3 comprises a matrix material 4 with a first refractive index, in which a plurality of light conversion particles 5 and a plurality of homogenization particles 6 are embedded. The particles 5, 6 form agglomerates 7 or accumulations within the conversion layer 3, which are formed during the manufacturing step of the conversion layer 3. The light conversion particles 5 are designed to convert light of a first wavelength emitted by the light emitting surface 2 into light of a second wavelength. The homogenization particles 6 consist of a material with a second refractive index, wherein the first and the second refractive index differ at most by a value of 0.1.

1.-16. (canceled)

17. An optoelectronic light emitting device comprising:
at least one light emitting surface configured to emit light of a first wavelength; and
a conversion layer arranged on the at least one light emitting surface,
wherein the conversion layer comprises a substantially transparent matrix material having a first refractive index in which it is embedded:
a plurality of light conversion particles configured to convert the light of the first wavelength into light of a second wavelength, and
a plurality of homogenization particles consisting essentially of a material having a second refractive index,
wherein the first and second refractive indices differ by a value of at most 0.1,
wherein the conversion layer has a thickness of less than or equal to 30 μm, and
wherein a particle size distribution of the light conversion particles substantially corresponds to a particle size distribution of the homogenization particles.

18. The optoelectronic light emitting device according to claim 17, wherein the at least one light emitting surface comprises an edge length of less than or equal to 40 μm, or an area of less than or equal to 100 μm².

19. The optoelectronic light emitting device according to claim 17, wherein the conversion layer further comprises light-scattering particles of a material having a third refractive index, and wherein the third refractive index differs from the first and the second refractive index.

20. The optoelectronic light emitting device according claim 17, wherein the optoelectronic light emitting device is an LED or a pixelated LED chip, and wherein the at least one light emitting surface is a light emitting surface of the LED or the pixelated LED chip.

21. The optoelectronic light emitting device according to claim 17, wherein the optoelectronic light emitting device comprises a wafer structure with a plurality of light emitting components grown on the wafer, and wherein the at least one light emitting surface are light emitting surfaces of the light emitting components grown on the wafer.

22. The optoelectronic light emitting device according to claim 17, wherein the matrix material comprises at least one of the following materials:
a silicone;
an epoxy; or
a material based on glass.

23. The optoelectronic light emitting device according to claim 17, wherein the homogenization particles comprise at least one of the following materials:
SiO₂;
highly refractive polymers;
PP;
PE; or
Al₂O₃.

24. The optoelectronic light emitting device according to claim 17, wherein a number of homogenization particles of all particles present in the conversion layer is at most 50%.

25. The optoelectronic light emitting device according to claim 17, wherein the particles embedded in the conversion layer have an inhomogeneous distribution.

26. The optoelectronic light emitting device according to claim 17, wherein agglomerates of particles embedded in the conversion layer are formed in the conversion layer, and wherein each of the agglomerates comprises a partial amount of the light conversion particles and a partial amount of the homogenization particles.

27. A method for manufacturing an optoelectronic light emitting device, the method comprising:
providing at least one light emitting surface of the optoelectronic light emitting device, the at least one light emitting surface for emitting light of a first wavelength; and
applying a conversion layer to the at least one light emitting surface,
wherein the conversion layer comprises a substantially transparent matrix material having a first refractive index in which it is embedded:
a plurality of light conversion particles for converting the light of the first wavelength into light of a second wavelength, and
a plurality of homogenization particles consisting of a material having a second refractive index,
wherein the first and second refractive indices differ by a value of at most 0.1,
wherein the conversion layer has a thickness of less than or equal to 30 μm; and
wherein a particle size distribution of the light conversion particles substantially corresponds to a particle size distribution of the homogenization particles.

28. The method according to claim 27, wherein applying the conversion layer comprises a spraying process.

29. The method according to claim 27, wherein applying the conversion layer comprises a electrophoretic deposition process.

30. The method according to claim 27, wherein a material of the conversion layer is in a form of a suspension while applying the conversion layer, wherein the material of the conversion layer comprises the matrix material, the light conversion particles and the homogenization particles, and wherein the suspension hardens after applying the conversion layer.

31. The method according to claim 27, wherein applying the conversion layer comprises a laminating process.
